(19) United States
(12) Patent Application Publication
(10) Pub. No.: US 2009/0280270 A1
(43) Pub. Date: Nov. 12, 2009

(54) Method and Device for the Hot Dip Coating of a Metal Strip

(76) Inventors: Holger Behrens, Erkrath (DE); Rolf Brisberger, Spielberg (AU); Olaf Norman Jepsen, Siegen (DE); Michael Zielenbach, Siegen (DE)

Correspondence Address: FRIEDRICH KUEFFNER, 317 MADISON AVENUE, SUITE 910, NEW YORK, NY, 10017, US

(21) Appl. No.: 11/887,504

(22) PCT Filed: Mar. 29, 2006
(86) PCT No.: PCT/EP2006/002844

§ 371 Date: Sep. 28, 2007

(30) Foreign Application Priority Data
Mar. 30, 2005 (DE) 10 2005 014 878.6

(51) Int. Cl. C23C 2/40; C23C 16/46

(52) U.S. Cl. 427/598; 118/672

(57) ABSTRACT

The invention relates to a method for the hot dip coating of a metal strip (1), in particular a steel strip, according to which the metal strip (1) is fed vertically through a container (3) that holds the molten coating metal (2) and a guide channel (4) that is connected upstream. According to the invention, to retain the coating metal (2) in the container (3) in the vicinity of the guide channel (4), an electromagnetic field is generated by means of at least two inductors (5) that are situated on either side of the metal strip (1) and to stabilise the metal strip (1) in a central position in the guide channel (4), the electromagnetic excitation of the inductors (5) is modified and/or an electromagnetic field that overlaps the electromagnetic field of the inductors (5) is generated by means of at least two correction coils (6) that are situated on either side of the metal strip (1). The aim of the invention is to control the centring of the metal strip in a manner that is not susceptible to interference. To achieve this, the stabilisation of the central position of the metal strip (1) in the guide channel (4) takes place in a closed-loop control circuit by the sequence of the following steps: a) measurement of the force (F_{H}) that acts in a horizontal direction and that the metal strip (1) exerts on a force measuring element (7) when it leaves the central position; b) the induction current (I_{I}) in the inductors (5) and/or on the induction current (I_{I}) in the correction coils (6) is influenced in accordance with the measured force (F_{H}), in order to hold the metal strip (1) in a central position in the guide channel (4). The invention also relates to a device for the hot dip coating of a metal strip.

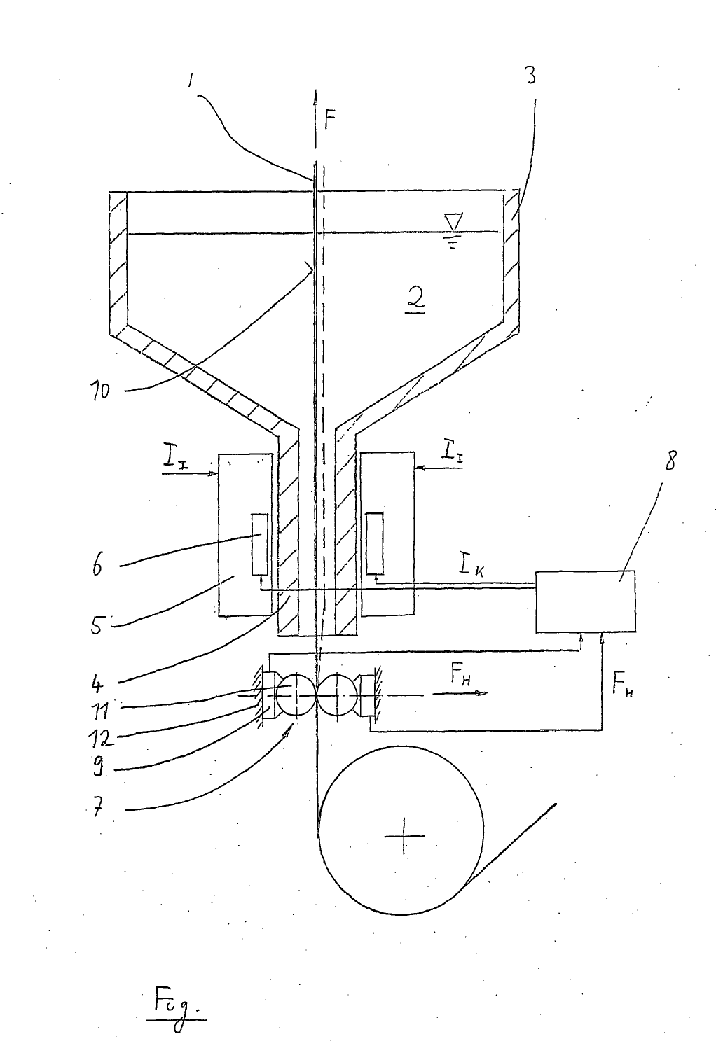

The invention concerns a method for hot dip coating a metal strand, especially a steel strip, in which the metal strip is passed vertically through a tank that contains the molten coating metal and through a guide channel upstream of the tank, where an electromagnetic field is generated in the area of the guide channel by means of at least two inductors installed on both sides of the metal strip in order to keep the coating metal in the tank, and where, in order to stabilize the metal strip in a center position in the guide channel, the electromagnetic excitation of the inductors is varied and/or an electromagnetic field superimposed on the electromagnetic field of the inductors is generated by means of at least two correction coils installed on both sides of the metal strip. The invention also concerns a device for hot dip coating a metal strip.

Conventional metal hot dip coating installations for metal strip have a high-maintenance part, namely, the tank and the fittings it contains. Before being coated, the surfaces of the metal strip must be cleaned of oxide residues and activated for bonding with the coating metal. For this reason, the strip surfaces are subjected to heat treatments in a reducing atmosphere before the coating operation is carried out. Since the oxide coatings are first removed by chemical or abrasive methods, the reducing heat treatment process activates the surfaces, so that after the heat treatment, they are present in a pure metallic state.

However, this activation of the strip surfaces increases their affinity for the surrounding atmospheric oxygen. To prevent the surface of the strip from being reexposed to atmospheric oxygen before the coating process, the strip is introduced into the hot dip coating bath from above in an immersion snout. Since the coating metal is present in the molten state, and since one would like to utilize gravity together with blowing devices to adjust the coating thickness, but the subsequent processes prohibit strip contact until the coating metal has completely solidified, the strip must be deflected in the vertical direction in the tank. This is accomplished with a roller that runs in the molten metal. This roller is subject to strong wear by the molten coating metal and is the cause of shutdowns and thus loss of production.

The desired low coating thicknesses of the coating metal, which can vary in the micrometer range, place high demands on the quality of the strip surface. This means that the surfaces of the strip-guiding rollers must also be of high quality. Problems with these surfaces generally lead to defects in the surface of the strip. This is a further cause of frequent plant shutdowns.

To avoid the problems associated with rollers running in the molten coating metal, solutions have been proposed, in which a tank is used that is open at the bottom and has a guide channel in its lower section for guiding the strip vertically upward, and in which an electromagnetic seal is used to seal the open bottom of the tank. The production of the electromagnetic seal involves the use of electromagnetic inductors, which operate with electromagnetic alternating or traveling fields that seal the tank at the bottom by means of a repelling, pumping, or constricting effect.

Solutions of this type are described, for example, in EP 0 854 940 B1, WO 2001/071051 Al, WO 2004/050940 A2, and WO 2004/050941 A1.

Although this approach is especially effective for the coating of nonferromagnetic metal strip, problems arise in the coating of steel strip, which is essentially ferromagnetic, because the strip is drawn to the walls of the channel in the electromagnetic seals by the ferromagnetic forces, and this damages the surface of the strip.

An unstable equilibrium exists with respect to the position of the ferromagnetic steel strip passing through the guide channel between two traveling-field inductors. The sum of the forces of magnetic attraction acting on the strip is zero only in the center of the guide channel. As soon as the steel strip is deflected from its center position, it draws closer to one of the two inductors and moves farther away from the other inductor. This type of deflection may be caused by simple flatness defects of the strip. Defects of this type include any type of strip waviness in the direction of strip flow, viewed over the width of the strip (center buckles, quarter buckles, edge waviness, flutter, twist, crossbow, S-shape, etc.). The magnetic induction, which is responsible for the magnetic attraction, decreases in field strength with increasing distance from the inductor according to an exponential function. Therefore, the force of attraction similarly decreases with the square of the induction field strength with increasing distance from the inductor. This means that when the strip is deflected in one direction, the force of attraction to one inductor increases exponentially, while the restoring force by the other inductor decreases exponentially. The two effects automatically potentiate each other, so that the equilibrium is unstable.

To solve this problem, i.e., to realize precise positioning of the metal strip in the guide channel, EP 0 854 940 B1 uses a method of strip stabilization in which the coils for generating the traveling field are used both for sealing and for strip stabilization, where the control of the magnetic field, whose field strength and/or frequency can be adjusted as a function of a sensor-detected position of the strip in the coating channel, is superimposed on the modulation of the electromagnetic traveling field.

To stabilize the center position of the metal strip in the guide channel, WO 2004/050940 A2 proposes a method involving the control of electromagnetic supplementary coils or correction coils, where, first, the position of the metal strip in the guide channel is measured, then the induction currents are measured in the inductors and in the supplementary coils, and then the induction current in the supplementary coils is controlled as a function of the measured parameters to keep the metal strip in a center position in the guide channel.

To determine the position of the metal strip in the guide channel for the purpose of automatically maintaining it in a center position, WO 2004/050941 A1 provides for the use of two coils, which, as viewed in the direction of conveyance of the metal strip, are arranged within the vertical extent of the inductors and between the inductors and the metal strip, and the voltage induced in the coils is measured to obtain an indication of the actual position of the metal strip in the guide channel.

All of the previously known methods are thus aimed at determining the position of the metal strip in the guide channel, and the position thus determined is used to control the inductors and/or the supplementary or correction coils by closed-loop control in such a way that the metal strip is kept as close as possible to the center of the guide channel.

It has been found that a procedure of this type often leads to problems, since the determination of the position of the metal strip must be made without contact in order to avoid damaging the surface of the metal strip in the region of the guide channel. Furthermore, known sensors (e.g., eddy-current sensors, laser sensors, or capacitive sensors) do not always operate perfectly in the environment of the very strong magnetic fields, so that the automatic control of the center position is not always reliable.

Therefore, the objective of the invention is to create a method and a corresponding device for hot dip coating a metal strip, which make it possible to overcome the stated disadvantages. In other words, the efficiency of the automatic control is to be improved to make it possible to maintain the metal strip in the center of the guide channel in a simpler way.

The objective of the invention with respect to the method is achieved by stabilizing the center position of the metal strip in the guide channel by the following sequence of steps in a closed-loop control system:

(a) measurement of the essentially horizontally acting force that the metal strip exerts on a force-measuring element when it deviates from the center position; and

(b) action to control the induction current in the inductors and/or the induction current in the correction coils as a function of the measured force to keep the metal strip in the center position in the guide channel.

In accordance with the basic idea of the invention, well-known mechanisms for controlling the currents of the inductors and/or correction coils are employed for automatically controlling the center position of the metal strip on the basis of the horizontal force that the metal strip exerts on a force-measuring element when it deviates from the center position. In other words—in contrast to the previously known solutions—it is not the deflection itself from the center position which is measured

In a first refinement of this method, the horizontally acting force is measured below the guide channel.

It is preferably provided—in a way that is already well known—that the electromagnetic field generated for sealing the tank is a polyphase traveling field generated by applying an alternating current with a frequency of 2 Hz to 2 kHz. Alternatively, a single-phase alternating field can be generated by applying an alternating current with a frequency of 2 kHz to 10 kHz.

The device for hot dip coating a metal strip, especially a steel strip, in which the metal strip is passed vertically through a tank that holds the molten coating metal and through a guide channel upstream of the tank, has at least two inductors installed on both sides of the metal strip in the area of the guide channel for generating an electromagnetic field for retaining the coating metal in the tank and, in accordance with the invention, is characterized by at least one force-measuring element for measuring the horizontally acting force that the metal strip exerts on a force-measuring element when it deviates from the center position in the guide channel and by an automatic control system that is suitable for controlling the induction current in the one or more inductors as a function of the measured force.

Besides the inductors, two correction coils are preferably installed on both sides of the metal strip, and the automatic control system is suitable for controlling their induction current.

It is especially preferred for the force-measuring element to be designed as a strip guide roller equipped with a load cell. The load cell can be designed as a strain gauge.

It is advantageous to install the force-measuring element below the guide channel. Furthermore, it is especially preferred for a force-measuring element to be installed on each side of the metal strip. In this way, the horizontal force of the strip can be easily determined in both directions of deflection from the center position.

One of the advantages of the invention is that it allows simple calibration of the measuring setup. In addition, the setup is not very susceptible to malfunctions, since sensors that are especially sensitive are not needed. For example, if the force-measuring elements are equipped with strain gauges, highly precise force measurement is still readily possible under rough surrounding conditions. The measuring elements that can be used to measure the force are very well known, which means that there is already extensive operating experience with them, so that it can be ensured that the measuring elements are well suited for continuous operation.

In particular, the strip surface and the surroundings do not play a significant role in the stabilization of the strip in the center plane. Neither the liquid coating metal nor the bright surface of the strip nor the strong magnetic field interfere with the method. The system thus shows very little susceptibility to malfunctions.

The sole figure is a schematic drawing of a specific embodiment of the invention. It shows a hot dip coating installation with a metal strip passing through it.

The hot dip coating installation has a tank 3, which is filled with molten coating metal 2. The molten coating metal 2 can be, for example, zinc or aluminum. The metal strip 1, e.g., a steel strip, is coated by passing it vertically upward through the tank 3 in direction of conveyance F. It should be noted at this point that it is also basically possible for the metal strip 1 to pass through the tank 3 from top to bottom. To allow passage of the metal strip 1 through the tank 3, the tank 3 is open at the bottom, where a guide channel 4 is located. The guide channel 4 is shown exaggeratedly large or wide in the drawing.

To prevent the molten coating metal 2 from flowing out at the bottom through the guide channel 4, two electromagnetic inductors 5 are located on either side of the metal strip 1. The electromagnetic inductors 5 induce a magnetic field, which counteracts the weight of the coating metal 2 and thus seals the guide channel 4 at the bottom.

The inductors 5 are two alternating-field or traveling-field inductors installed opposite each other. They are operated in a frequency range of 2 Hz to 10 kHz and induce an electromagnetic transverse field perpendicular to the direction of conveyance F. The preferred frequency range for single-phase systems (alternating-field inductors) is 2 kHz to 10 kHz, and the preferred frequency range for polyphase systems (e.g., traveling-field inductors) is 2 Hz to 2 kHz.

The goal is to hold the metal strip 1, which is located in the guide channel 4, in such a way that it is positioned as closely as possible to the center plane 10 of the guide channel 4.

The metal strand 1 between the two opposing inductors 5 is generally drawn towards whichever inductor is closer when an electromagnetic field is induced between the inductors 5, and the attraction increases the more closely the metal strip 1 approaches the inductor, which leads to an extremely unstable strip center position. During the operation of the installation, this results in the problem that the metal strip 1 cannot run freely and centrally through the guide channel 4 between the activated inductors 5 due to the force of attraction of the inductors 5.

Therefore, to stabilize the metal strip 1 in the center plane 10 of the guide channel 4, correction coils 6 are installed on both sides of the guide channel 4 or metal strip 1. The correction coils 6 are controlled by an automatic control system 8 in such a way that the superposition of the magnetic fields of the inductors 5 and the correction coils 6 always keeps the metal strip 1 in the center of the guide channel 4.

Accordingly, depending on their degree of activation, the correction coils 6 can intensify or weaken the magnetic field of the inductors 5 (superposition principle of magnetic fields). This makes it possible to control the position of the metal strip 1 in the guide channel 4.

A pair of force-measuring elements 7 is located below the guide channel 4, specifically, one force-measuring element 7 on each side of the metal strip 1. Each force-measuring element has a strip guide roller 11, which rests against the metal strip 1. A load cell 9 in the form of a strain gauge is installed between the strip guide roller 11 and the roller carrier 12 (shown only schematically). The load cell makes it possible to measure the magnitude of the horizontal force F_{H} that the strip 1 exerts on the force-measuring element 7. In this connection, a broken line is used in the drawing to indicate a position of the metal strip 1 in which the strip is not centered in the guide channel 4 but rather is deflected to the right of the center plane 10 (shown with strong exaggeration).

As a result of the fact that the metal strip 1, which is under strip tension, exerts a horizontal force component F_{H} towards the right on the force-measuring element 7 in the position of the metal strip 1 indicated by the broken line in the drawing, the load cell records a horizontal force that differs from zero. The measured value is relayed to the automatic control system 8.

The automatic control system 8 thus receives the value and the direction of the horizontally acting force F_{H} as input variables. Algorithms that control the induction current I_{K} in the correction coils 6 on the basis of the prevailing horizontal force F_{H} are stored in the automatic control system 8. If, for example—as shown in the drawing—the strip is deflected towards the right from the center plane 10, a horizontal force towards the right is produced, and this force is measured by the right force-measuring element 7. This causes the automatic control system 8 to control the left correction coil 6 by increasing its induction current I_{K}, with the result that the strip 1 is drawn more strongly to the left and thus moves back towards its set position (center plane 10). In this way, the position of the metal strip 1 is maintained by the closed-loop control system in such a way that the deviations of the position of the metal strip 1 from the center plane 10 are minimized.

The greater the deviation from the center plane 10 becomes, the greater also becomes the angle of wrap of the respective strip guide roller 11 of the force-measuring element 7. Due to the strip tension, a correspondingly correlated value is obtained for the horizontal force F_{H}.

It is also conceivable to carry out the invention with only a single force-measuring element 7, for in this case, if the strip deviates to the right, a greater angle of wrap of the strip guide roller 11 and thus a correspondingly greater horizontal force would then be produced. On the other hand, if the strip 1 deviates to the left, the angle of wrap of the strip 1 would gradually decrease—until the strip 1 lifts completely from the strip guide roller 11, so that it can be determined that the strip is deviating to the left.

Due to the magnetic fields, without automatic control, the only positions of the metal strip 1 which are stable are those in which the strip rests against the wall of the guide channel 4 on the left or the right. The strip can be systematically moved into these two positions by means of the correction coils 6, which allows simple calibration of the measuring device. Any force value between the two limits can then be used as the set value for the automatic position control system; ideally, the corresponding set position is the center position according to the center plane 10.

Therefore, the metal strip 1 does not come into contact with the wall of the guide channel 4 when the invention is carried out properly, so that high-quality hot dip coating can be realized.

### LIST OF REFERENCE SYMBOLS

1 metal strip (steel strip)
2 coating metal
3 tank
4 guide channel
5 inductor
6 correction coil
7 force-measuring element
8 automatic control system
9 load cell
10 center plane
11 strip guide roller
12 carrier
F_{H} horizontally acting force
I_{I} induction current in the inductors
I_{K} induction current in the correction coils
F direction of conveyance

1. A method for hot dip coating a metal strip (1), especially a steel strip, in which the metal strip (1) is passed vertically through a tank (3) that contains the molten coating metal (2) and through a guide channel (4) upstream of the tank (3), where an electromagnetic field is generated in the area of the guide channel (4) by means of at least two inductors (5) installed on both sides of the metal strip (1) in order to keep the coating metal (2) in the tank (3), and where, in order to stabilize the metal strip (1) in a center position in the guide channel (4), the electromagnetic excitation of the inductors (5) is varied and/or an electromagnetic field superimposed on the electromagnetic field of the inductors (5) is generated by means of at least two correction coils (6) installed on both sides of the metal strip (1), wherein the center position of the metal strip (1) in the guide channel (4) is stabilized by the following sequence of steps in a closed-loop control system:
(a) measurement of the horizontally acting force (F_{H}) that the metal strip (1) exerts on a force-measuring element (7) when it deviates from the center position;
(b) action to control the induction current (I_{I}) in the inductors (5) and/or the induction current (I_{K}) in the correction coils. (6) as a function of the measured force (F_{H}) to keep the metal strip (1) in the center position in the guide channel (4).

2. A method in accordance with claim 1, wherein the horizontally acting force (F_{H}) is measured below the guide channel (4).

3. A method in accordance with claim 1, wherein the electromagnetic field is a polyphase traveling field generated by applying an alternating current with a frequency of 2 Hz to 2 kHz.

4. A method in accordance with claim 1, wherein the electromagnetic field is a single-phase alternating field generated by applying an alternating current with a frequency of 2 kHz to 10 kHz.

5. A device for hot dip coating a metal strip (1), especially a steel strip, in which the metal strip (1) is passed vertically through a tank (3) that contains the molten coating metal (2) and through a guide channel (4) upstream of the tank (3), with at least two inductors (5, 6) installed on both sides of the metal strip (1) in the area of the guide channel (4) for generating an electromagnetic field for retaining the coating metal (2) in the tank (3), wherein at least one force-measuring element (7) for measuring the horizontally acting force (F_{H}) that the metal strip (1) exerts on a force-measuring element (7) when it deviates from the center position in the guide channel (4) and by an automatic control system (8) that is suitable for controlling the induction current (I_{I}, I_{K}) in the one or more inductors (5, 6) as a function of the measured force (F_{H}).

6. A device in accordance with claim 5, wherein, besides the inductors (5), two correction coils (6) are installed on both sides of the metal strip (1), where the automatic control system (8) is suitable for controlling their induction current (I_{K}).

7. A device in accordance with claim 5, wherein the force-measuring element (7) is designed as a strip guide roller equipped with a load cell (9).

8. A device in accordance with claim 7, wherein the load cell (9) is designed as a strain gauge.

9. A device in accordance with claim 5, wherein the force-measuring element (7) is installed below the guide channel (4).

10. A device in accordance with claim 5, wherein a force-measuring element (7) is installed on each side of the metal strip (1).
